(19) United States
(12) Patent Application Publication
(10) Pub. No.: US 2009/0057799 A1
(43) Pub. Date: Mar. 5, 2009

(54) Sensor semiconductor device and method for fabricating the same

(75) Inventors: Chang-Yueh Chan, Taichung (TW); Chih-Ming Huang, Hsinchu Hsein (TW); Chien-Ping Huang, Taichung (TW); Chin-Huang Chang, Taichung Hsien (TW); Cheng-Hsu Hsiao, Taichung (TW)

Correspondence Address: EDWARDS ANGELL PALMER & DODGE LLP, P.O. BOX 55874, BOSTON, MA, 02205, US

(73) Assignee: Siliconware Precision Industries Co., Ltd., Taichung (TW)

(21) Appl. No.: 12/229,651

(22) Filed: Aug. 26, 2008

(30) Foreign Application Priority Data
Aug. 27, 2007 (CN) 096131618

(51) Int. Cl. H01L 31/00; H01L 21/00

(52) U.S. Cl. 257/433; 438/64; 257/E31.001; 257/E21.001

(57) ABSTRACT

A sensor semiconductor device and a method for fabricating the same are provided. At least one sensor chip is mounted and electrically connected to a lead frame. A first and a second encapsulation molding processes are sequentially performed to form a transparent encapsulant for encapsulating the sensor chip and a part of the lead frame and to form a light-impervious encapsulant for encapsulating the transparent encapsulant. The transparent encapsulant has a light-pervious portion formed at a position corresponding to and above a sensor zone of the sensor chip. The light-pervious portion is exposed from the light-impervious encapsulant. Light may penetrate the light-pervious portion, without using an additional cover board, thereby reducing manufacturing steps and costs. The above arrangement avoids prior-art problems of poor reliability caused by a porous encapsulant and poor signal reception caused by interference of ambient light entering into a conventional chip only encapsulated by a transparent encapsulant.

### BACKGROUND OF THE INVENTION

1. Field of the Invention

This invention generally relates to semiconductor devices and methods for fabricating the same, and more specifically, to an image sensor semiconductor device and a method for fabricating the same.

2. Description of Related Art

Referring to FIG. 1, a method for fabricating a conventional image sensor package mainly comprises providing a lead frame 10, forming a dam-like structure 11 with a receiving space 110 on the lead frame 10 using an encapsulation mold by means of pre-mold, disposing a sensor chip 12 in the receiving space 110 of the dam-like structure 11 and electrically connecting the sensor chip 12 to the lead frame 10 via bonding wires 13, disposing a glass 14 on the dam-like structure 11 to cover and seal the sensor chip 12 such that image light can be caught by the sensor chip 12. Thereafter, the completed image sensor package is ready to be integrated with an external device such as a printed circuit board (PCB) so as to be employed in various electronic products such as digital still cameras (DSC), digital camcorders, optical mice, cell phones, and so on. Related techniques are disclosed by U.S. Pat. Nos. 6,420,204, 5,436,492, 6,643,919, 6,291,263, and 6,384,472.

However, for those low-level sensor packages such as optical mice, the foresaid processes of high-level hermetic technique are not required. U.S. Pat. Nos. 6,967,321, 7,045,775, and 7,148,078 disclose a package technique of injection molding. As shown in FIGS. 2A through 2D, a lead frame 20 is provided, surface of which is plated with a layer of gold (Au) (not shown in the drawing) for providing a better subsequent electricity connection to a sensor chip. Then, a porous colloid structure 21 that has a receiving space 210 formed at central position thereof is formed by means of injection molding; wherein since the employed injection molding mold (not shown in the drawing) has a plurality of abutting needle structures for tightly abutting against the lead frame 20, as shown in FIG. 2A, the completed encapsulant by injection molding has a plurality of needle holes 28. As shown in FIG. 2B, a sensor chip 22 is disposed on the lead frame 20 and received in the receiving space 210 of the porous colloid structure 21, and the sensor chip 22 is electrically connected to the lead frame 20 via bonding wires 23. As shown in FIG. 2C, a transparent glue 24 is coated inside the receiving space 210 of the porous colloid structure 21 to encapsulate the sensor chip 22 and the bonding wires 23. As shown in FIG. 2D, the porous colloid structure 21 is covered with a light-impervious cover board 25, wherein an aperture 250 is formed in the light-impervious cover board 25 for allowing light to reach the sensor chip 22 via the aperture 250, and the leads of the lead frame 20 are bent so as to obtain a low-level sensor package.

As mentioned above, since the prior injection molding mold has a plurality of abutting needle structures in order to make the injection molding mold tightly abut against the lead frame, a plurality of abutting needle holes are left in the encapsulant. Accordingly, moisture is easy to enter and pollute the sensor chip. Further, in order to prevent residual particles from being generated in the porous colloid structure made through injection molding, an additional step of coating transparent glue is required, thus increasing the fabrication cost. In addition, a light-impervious cover board is further employed to cover the transparent glue, which not only increases the process steps but also raises production cost. Besides, the foresaid injection molding process must employ a gold-plated lead frame, which makes production cost even higher.

Taiwan Patent No. 473954 discloses a package that employs a transparent resin to completely encapsulate a sensor chip. However, when this kind of package is practically applied to light sensor electronic devices such as optical mice, light can easily enter into the package from the side thereof. As a result, a lot of noise can be generated, which adversely affects correct signal transmission of the sensor chip. Therefore, the practical application of the above-described package is quite limited.

Accordingly, it is a high urgent issue in the industry for how to provide a sensor semiconductor device and a method for fabricating the same, which eliminates the need of a specific gold-plated lead frame and additional cover board so as to reduce process steps and cost, and meanwhile avoids porous colloid structure made by injection molding and additionally coated transparent glue, and also prevents noise from generation caused by ambient interference light entering into the sensor chip.

### SUMMARY OF THE INVENTION

In view of the disadvantages of the prior art mentioned above, it is an objective of the present invention to provide a sensor semiconductor device and a method for fabricating the same, wherein neither a specific gold-plated lead frame nor an additional cover board is required, thereby reducing process steps and cost. It is another objective of the present invention to provide a sensor semiconductor device and a method for fabricating the same, which is capable of avoiding problem of poor reliability due to porous colloid structure made by injection molding in the prior art.

It is a further objective of the present invention to provide a sensor semiconductor device and a method for fabricating the same, which eliminates the need of additional coating of transparent glue for preventing pollution of residual particles generated during injection molding.

It is still another objective of the present invention to provide a sensor semiconductor device and a method for fabricating the same, which is capable of avoiding noise caused by ambient light entering into the sensor chip that is only encapsulated by transparent resin.

To achieve the aforementioned and other objectives, the present invention provides a fabrication method of a sensor semiconductor device, comprising the steps of: providing a chip carrier, and disposing and electrically connecting at least one sensor chip to the chip carrier; forming a transparent encapsulant encapsulating the sensor chip and a part of the chip carrier, wherein the transparent encapsulant has a light-pervious portion formed at a position corresponding to and above a sensor zone of the sensor chip; and forming a light-impervious encapsulant encapsulating the transparent encapsulant, with the light-pervious portion of the transparent encapsulant being exposed from the light-impervious encapsulant.

The chip carrier is, for instance, a lead frame, which has a die pad for mounting the sensor chip and a plurality of leads disposed around the die pad for external electrical connections.

The transparent encapsulant can be formed on opposite first and second surfaces of the chip carrier for encapsulating the sensor chip, or it can be formed only on the first surface of the chip carrier where the sensor chip is disposed for encapsulating the sensor chip.

The light-pervious portion can be, for instance, a protruding portion formed on a surface of the transparent encapsulant, and the protruding portion has a sunken hole formed therein for penetration of light. Besides, a surface of the protruding portion can further be coated with an opaque material to reduce light interference. Alternatively, the light-pervious portion can be a concave portion formed at the surface of the transparent encapsulant, and an opening corresponding to the concave portion of the transparent encapsulant is formed in a surface of the light-impervious encapsulant to expose the light-pervious portion. Alternatively, the light-pervious portion can be a concave portion formed at the surface of the transparent encapsulant, and the surface of the transparent encapsulant with the concave portion is exposed from the light-impervious encapsulant, and then an opaque material can be coated on the surface of the transparent encapsulant exposed from the light-impervious encapsulant, with the concave portion of the transparent encapsulant being exposed from the opaque material.

In addition, a rough structure can be formed on a contact surface between the transparent encapsulant and the light-impervious encapsulant for enhancing bonding between the transparent encapsulant and the light-impervious encapsulant.

The present invention further discloses a sensor semiconductor device comprising: a chip carrier; at least one sensor chip disposed on and electrically connected to the chip carrier, wherein the sensor chip has a sensor zone; a transparent encapsulant encapsulating the sensor chip and a part of the chip carrier, wherein the transparent encapsulant has a light-pervious portion formed at a position corresponding to and above the sensor zone of the sensor chip; and a light-impervious encapsulant encapsulating the transparent encapsulant, with the light-pervious portion of the transparent encapsulant being exposed from the light-impervious encapsulant.

Therefore, according to the sensor semiconductor device and the method for fabricating the same of the present invention, at least one sensor chip is disposed on and electrically connected to a chip carrier, such as a lead frame. Then a first and a second encapsulation molding processes are sequentially performed to form a transparent encapsulant that encapsulates the sensor chip and a part of the lead frame and to form a light-impervious encapsulant that encapsulates the transparent encapsulant, wherein the transparent encapsulant has a light-pervious portion formed on at a position corresponding to and above a sensor zone of the sensor chip, and the light-pervious portion of the transparent encapsulant is exposed from the light-impervious encapsulant. Accordingly, the present invention only needs to perform two sequential encapsulation molding processes to form a transparent encapsulant and a light-impervious encapsulant on the lead frame to encapsulate the sensor chip, and make the light-pervious portion of the transparent encapsulant be exposed from the light-impervious encapsulant so as to allow penetration of light. Therefore, the present invention eliminates the need of a specific gold-plated lead frame and additional cover board, thereby simplifying the fabrication process and reducing the fabrication cost. Also, the present invention is capable of avoiding prior problems of poor reliability due to porous colloid structure made by injection molding and higher cost due to additional coating of transparent glue for preventing pollution of residual particles. In addition, the present invention forms a light-impervious encapsulant to encapsulate the transparent encapsulant, thereby being capable of preventing noise caused by ambient interference light entering into the sensor chip that is only encapsulated by a transparent resin.

### BRIEF DESCRIPTION OF DRAWINGS

The present invention can be more fully understood by reading the following detailed description of the preferred embodiments, with reference made to the accompanying drawings, wherein:

FIG. 1 is a diagram of a conventional image sensor package;

FIGS. 2A to 2D are diagrams showing an injection molding method for fabricating a conventional image sensor package;

FIGS. 3A through 3F are diagrams showing a sensor semiconductor device and a method for fabricating the same according to a first embodiment of the present invention;

FIG. 4 is a diagram showing a sensor semiconductor device and a method for fabricating the same according to a second embodiment of the present invention;

FIG. 5 is a diagram of a sensor semiconductor device and a method for fabricating the same according to a third embodiment of the present invention;

FIGS. 6A through 6C are diagrams showing a sensor semiconductor device and a method for fabricating the same according to a fourth embodiment of the present invention;

FIGS. 7A and 7B are diagrams showing a sensor semiconductor device and a method for fabricating the same according to a fifth embodiment of the present invention; and

FIG. 8 is a diagram showing a sensor semiconductor device and a method for fabricating the same according to a sixth embodiment of the present invention.

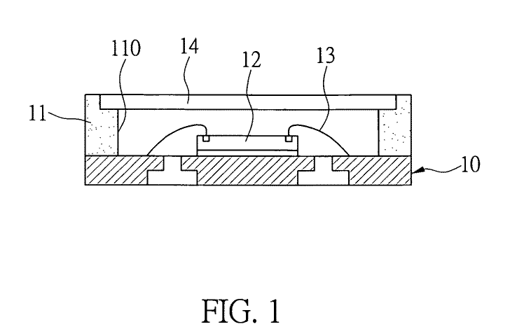

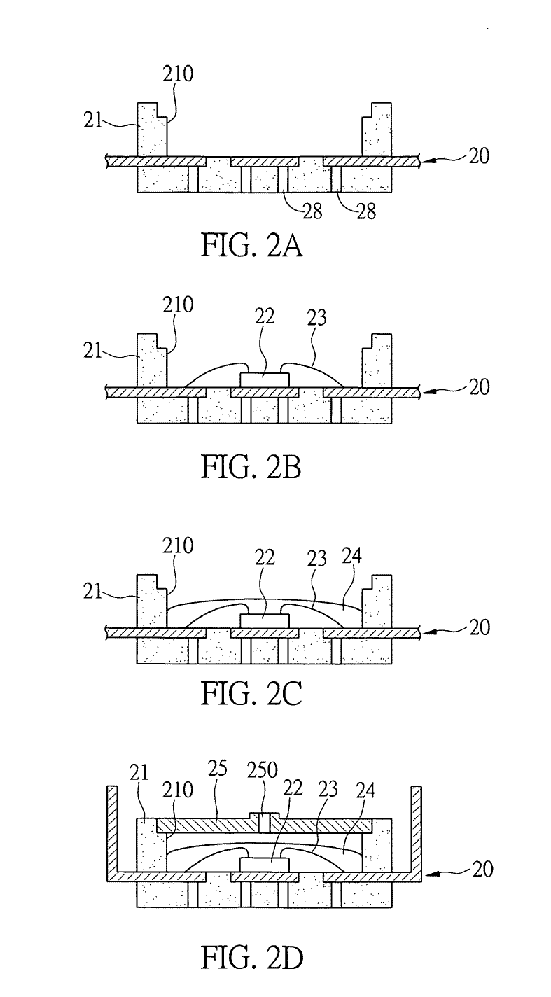

### DETAILED DESCRIPTION OF PREFERRED EMBODIMENTS

The following illustrative embodiments are provided to illustrate the disclosure of the present invention, these and other advantages and effects can be apparently understood by those in the art after reading the disclosure of this specification. The present invention can also be performed or applied by other different embodiments. The details of the specification may be on the basis of different points and applications, and numerous modifications and variations can be devised without departing from the spirit of the present invention.

### First Embodiment

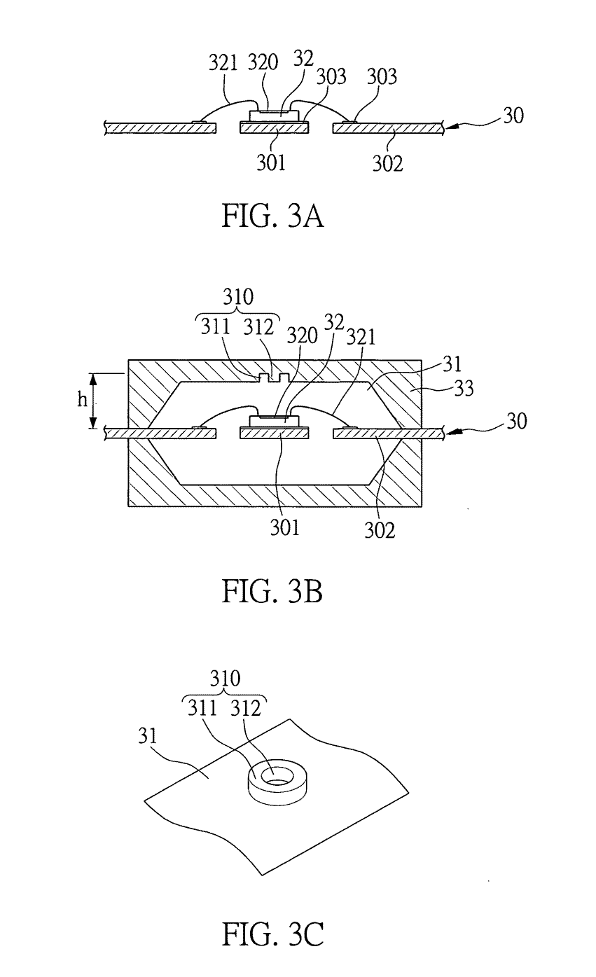

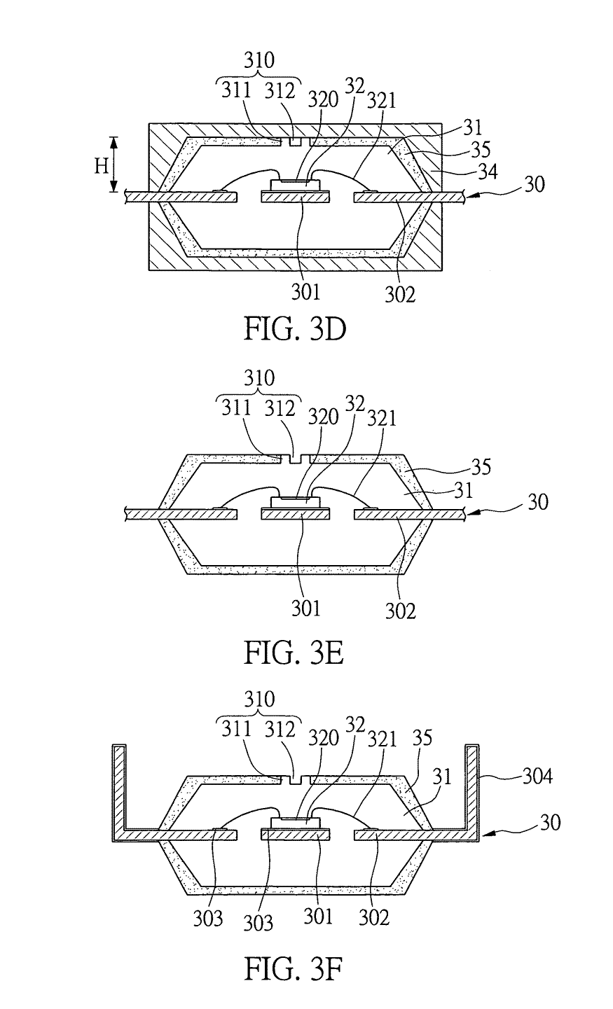

Please refer to FIGS. 3A through 3F, which are diagrams illustrating a sensor semiconductor device and a method for fabricating the same according to the first embodiment of the present invention.

As shown in FIG. 3A, a chip carrier is provided, and at least one sensor chip is disposed on and electrically connected to the chip carrier.

The chip carrier is, for instance, a lead frame 30, which has a die pad 301 and a plurality of leads 302 disposed around the die pad 301. The lead frame 30 is made of copper (Cu), and first surfaces of the die pad 301 and inner ends of the leads 302 can be plated with silver (Ag) 303 such that at least one sensor chip 32 that has a sensor zone 320 on its active surface can be disposed on the first surface of the die pad 301, and the sensor chip 32 is electrically connected to the inner ends of the leads 302 via a plurality of bonding wires 321.

As shown in FIG. 3B, the lead frame 30 with the sensor chip 32 disposed thereon is disposed in a first encapsulation mold 33 to perform a first encapsulation molding process such that a transparent encapsulant 31 made of a transparent resin can be formed on the opposite first and second surfaces of the lead frame 30 to encapsulate the sensor chip 32 and part of the lead frame 30. Meanwhile, outer ends of the leads 302 are exposed from the transparent encapsulant 31. Therein, the transparent encapsulant 31 has a light-pervious portion 310 formed on at a position corresponding to and above the sensor zone 320 of the sensor chip 32.

Further referring to FIG. 3C, the light-pervious portion 310 is a protruding portion 311 formed on surface of the transparent encapsulant 31, and the protruding portion 311 has a sunken hole 312 formed therein to allow penetration of light. Depth of the sunken hole 312 is about 0.5-1 mm, preferably 0.5 mm.

As shown in FIGS. 3D and 3E, after the first encapsulation mold 33 is removed, the lead frame 30 with the transparent encapsulant 31 encapsulating the sensor chip 32 is disposed in a second encapsulation mold 34 and the protruding portion 311 of the transparent encapsulant 31 is abutted against top surface of the molding cavity of the second encapsulation mold 34 so as to perform a second encapsulation molding process, wherein distance h (as shown in FIG. 3B) from the first surface of the lead frame 30 to top edge of the protruding portion 311 of the transparent encapsulant 31 is about 0.05 to 0.15 mm greater than distance H from the first surface of the lead frame 30 to top surface of the molding cavity of the second encapsulation mold 34 such that the protruding portion 311 of the transparent encapsulant 31 can be completely abutted against the top surface of the molding cavity of the second encapsulation mold 34, thereby forming a light-impervious encapsulant 35 made of a conventional black molding resin to encapsulate the transparent encapsulant 31 and meanwhile making the light-pervious portion 310 of the transparent encapsulant 31 be exposed from the light-impervious encapsulant 35 and preventing the black molding resin from overflowing to the protruding portion 311 of the transparent encapsulant 31.

Next, the second encapsulation mold 34 is removed, thereby forming the light-impervious encapsulant 35 for encapsulating the transparent encapsulant 31, and also the light-pervious portion 310 of the transparent encapsulant 31 and outer ends of the leads 302 are exposed from the light-impervious encapsulant 35.

As shown in FIG. 3F, the outer ends of the leads 302 exposed from the light-impervious encapsulant 35 are coated with tin (Sn) or solder material 304, and then the leads 302 are bent so as to obtain a sensor semiconductor device of the present invention.

By means of the foresaid method, the present invention further discloses a sensor semiconductor device, which comprises: a chip carrier such as a lead frame 30; at least one sensor chip 32 disposed on and electrically connected to the lead frame 30; a transparent encapsulant 31 encapsulating the sensor chip 32 and part of the lead frame 30, wherein the transparent encapsulant 31 has a light-pervious portion 310 formed on at a position corresponding to and above a sensor zone 320 of the sensor chip 32; and a light-impervious encapsulant 35 encapsulating the transparent encapsulant 31, the light-pervious portion 310 of the transparent encapsulant 31 being exposed from the light-impervious encapsulant 35. The lead frame 30 has a die pad 301 for mounting of the sensor chip 32, and a plurality of leads 302 disposed around the die pad 301 for external electrical connection. Surfaces of the die pad 301 and inner ends of the leads 302 are plated with silver 303 such that the sensor chip 32 can be disposed on the die pad 301 and electrically connected to the inner ends of the leads 302 via bonding wires. The outer ends of the leads 302 are exposed from the transparent encapsulant 31 and the light-impervious encapsulant 35, and surfaces of the exposed outer ends of the leads 302 are plated with tin or solder material 304 for external electrical connection.

Therefore, according to the sensor semiconductor device and the method for fabricating the same of the present invention, at least one sensor chip is disposed on and electrically connected to a chip carrier, such as a lead frame. Then a first and a second encapsulation molding processes are sequentially performed to form a transparent encapsulant that encapsulates the sensor chip and a part of the lead frame and to form a light-impervious encapsulant that encapsulates the transparent encapsulant, wherein the transparent encapsulant has a light-pervious portion formed on at a position corresponding to and above a sensor zone of the sensor chip, and the light-pervious portion of the transparent encapsulant is exposed from the light-impervious encapsulant. Accordingly, the present invention only needs to perform two sequential encapsulation molding processes to form a transparent encapsulant and a light-impervious encapsulant on the lead frame to encapsulate the sensor chip, and make the light-pervious portion of the transparent encapsulant be exposed from the light-impervious encapsulant so as to allow penetration of light. Therefore, the present invention eliminates the need of a specific gold-plated lead frame and additional cover board, thereby simplifying the fabrication process and reducing the fabrication cost. Also, the present invention is capable of avoiding prior problems of poor reliability due to porous colloid structure made by injection molding and higher cost due to additional coating of transparent glue for preventing pollution of residual particles. In addition, the present invention forms a light-impervious encapsulant to encapsulate the transparent encapsulant, thereby being capable of preventing noise caused by ambient interference light entering into the sensor chip that is only encapsulated by a transparent resin.

### Second Embodiment

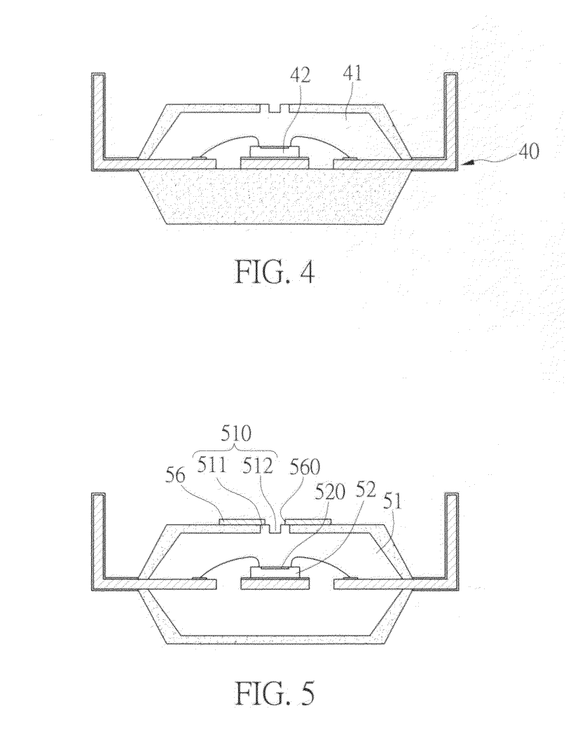

Please refer to FIG. 4, which is a diagram of a sensor semiconductor device and a method for fabricating the same according to a second embodiment of the present invention.

The present embodiment is mostly the same as the foresaid embodiment, the main difference is that, in the present embodiment, the transparent encapsulant 41 is only formed on one side of the lead frame 40 disposed with the sensor chip 42 so as to encapsulate the sensor chip 42, thereby reducing usage of transparent resin.

### Third Embodiment

Please refer to FIG. 5, which is a diagram showing a sensor semiconductor device and a method for fabricating the same according to a third embodiment of the present invention.

The sensor semiconductor device and the method for fabricating the same in the present embodiment are mostly the same as in the foresaid embodiments, the main difference is that, in the present embodiment, in order to reduce light interference, an opaque material 56, such as black ink is coated on the light-pervious portion 510 of the transparent encapsulant 51 at a position corresponding to the sensor zone 520 of the sensor chip 52, that is, the opaque material 56 is coated on surface of the protruding portion 511 formed on surface of the transparent encapsulant 51.

The opaque material 56 has an opening formed to expose the sunken hole 512 of the protruding portion 511 and part area of the protruding portion 511 around the sunken hole 512, wherein the area of the opening 560 is about 1.1 to 1.5 times of the area of the sunken hole 512, preferably the area of the opening 560 is 1.1 times of the area of the sunken hole 512.

### Fourth Embodiment

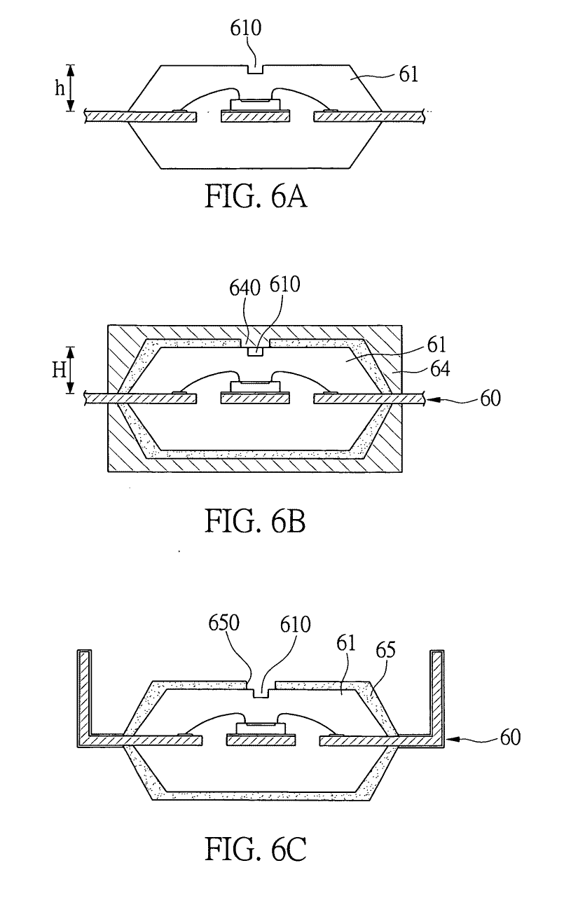

Please refer to FIGS. 6A through 6C, which are diagrams of a sensor semiconductor device and a method for fabricating the same according to a fourth embodiment of the present invention.

The sensor semiconductor device and the method for fabricating the same in the present embodiment are mostly the same as in the foresaid embodiments, the main differences are: in the present embodiment, the light-pervious portion of the transparent encapsulant 61 is a concave portion 610, and the second encapsulation mold 64 for performing the second encapsulation molding process has a protruding portion 640 formed on top surface of its molding cavity is provided, wherein position of the protruding portion 640 corresponds to position of the concave portion 610 of the transparent encapsulant 61, and the area of the protruding portion 640 is about 1.1 to 1.5 times of the area of the concave portion 610 of the transparent encapsulant 61, preferably the area of the protruding portion 640 is 1.1 times of the area of the concave portion 610 of the transparent encapsulant 61. Meanwhile, distance h from the first surface of the lead frame 60 to surface of the transparent encapsulant 61 is about 0.05 mm to 0.15 mm greater than distance H from the first surface of the lead frame 60 to surface of the protruding portion 640 of the second encapsulation mold 64, thus allowing surface of the transparent encapsulant 61 with the concave portion 610 disposed thereon to be completely abutted against the protruding portion 640 of the second encapsulation mold 64 and meanwhile preventing black molding resin filled inside the second encapsulation mold 64 from overflowing.

Next, the second encapsulation mold 64 is removed so as to form a light-impervious encapsulant 65 that encapsulates the transparent encapsulant 61, also an opening 650 is formed in the light-impervious encapsulant 65 to expose the concave portion 610 (light-pervious portion) of the transparent encapsulant 61. The area of the opening 650 is about 1.1 to 1.5 times of the area of the concave portion 610 of the transparent encapsulant 61, and preferably the area of the opening 650 is 1.1 times of the area of the concave portion 610.

### Fifth Embodiment

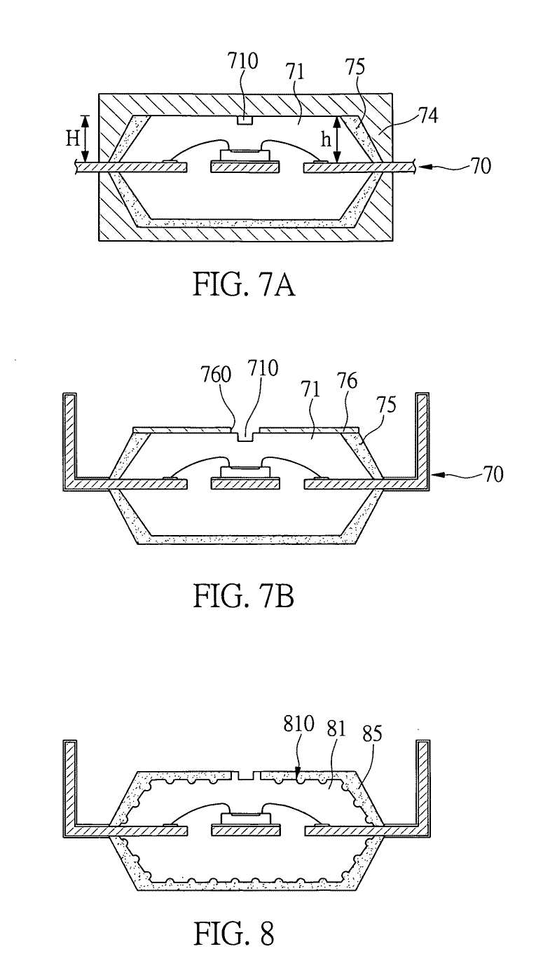

Please refer to FIGS. 7A and 7B, which are diagrams of a sensor semiconductor device and a method for fabricating the same according to a fifth embodiment of the present invention.

The sensor semiconductor device and the method for fabricating the same of the present embodiment are mostly the same as the foresaid embodiments, the main differences are: in the present embodiment, the light-pervious portion of the transparent encapsulant 71 is a concave portion 710, and when a second encapsulation molding process is performed, surface of the transparent encapsulant 71 with the concave portion 710 is directly abutted against top surface of the mold cavity of the second encapsulation mold 74 so as to form a light-impervious encapsulant 75 to encapsulate the transparent encapsulant 71. Also, surface of the transparent encapsulant 71 disposed with the concave portion 710 is even with surface of the light-impervious encapsulant 75 and exposed from the light-impervious encapsulant 75. Therein, distance h from the first surface of the lead frame 70 to surface of the transparent encapsulant 71 disposed with the concave portion 710 is about 0.05 mm to 0.15 mm greater than distance H from the first surface of the lead frame 70 to the top surface of the mold cavity of the second encapsulation mold 74 such that the surface of the transparent encapsulant 71 disposed with the concave portion 710 can be completely abutted against the top surface of the mold cavity of the second encapsulation mold 74, thereby preventing black molding resin filled inside the molding cavity from overflowing while forming the light-impervious encapsulant 75.

Next, an opaque material 76, such as black ink, is coated on surface of the transparent encapsulant 71 exposed from the light-impervious encapsulant 75, wherein an opening 760 is formed in the opaque material 76 corresponding to the concave portion 710 of the transparent encapsulant 71 for exposing the concave portion 710. The area of the opening 760 is about 1.1 to 1.5 times of the area of the concave portion 710, and preferably the area of the opening 760 is 1.1 times of the area of the concave portion 710.

### Sixth Embodiment

Please refer to FIG. 8, which is a sensor semiconductor device and a method for fabricating the same according to a sixth embodiment of the present invention.

The sensor semiconductor device and the method for fabricating the same of the present embodiment are mostly the same as in the foresaid embodiments, the main difference is: in the present embodiment, a rough structure 810 such as a sunken hole, a furrow, or a protruding portion, is further formed on surface of transparent encapsulant 81 for enhancing bonding between the transparent encapsulant 81 and the light-impervious encapsulant 85.

The foregoing descriptions of the detailed embodiments are only illustrated to disclose the features and functions of the present invention and not restrictive of the scope of the present invention. It should be understood to those in the art that all modifications and variations according to the spirit and principle in the disclosure of the present invention should fall within the scope of the appended claims.

What is claimed is:

1. A method for fabricating a sensor semiconductor device, comprising the steps of:
providing a chip carrier, and disposing and electrically connecting at least one sensor chip to the chip carrier;
forming a transparent encapsulant encapsulating the sensor chip and a part of the chip carrier, wherein the transparent encapsulant has a light-pervious portion formed at a position corresponding to and above a sensor zone of the sensor chip; and
forming a light-impervious encapsulant encapsulating the transparent encapsulant, with the light-pervious portion of the transparent encapsulant being exposed from the light-impervious encapsulant.

2. The method of claim 1, wherein the chip carrier is a lead frame having a die pad and a plurality of leads disposed around the die pad, the at least one sensor chip is disposed on the die pad and is electrically connected to inner ends of the leads via a plurality of bonding wires, and outer ends of the leads are exposed from the transparent encapsulant and the light-impervious encapsulant.

3. The method of claim 2, wherein the lead frame is made of copper (Cu), surfaces of the die pad and the inner ends of the leads are plated with silver (Ag), and surfaces of the outer ends of the leads are plated with tin (Sn) or a solder material.

4. The method of claim 1, wherein the light-pervious portion is a protruding portion formed on a surface of the transparent encapsulant, and a sunken hole is formed in the protruding portion for penetration of light.

5. The method of claim 4 further comprising covering a part of the protruding portion with an opaque material, and forming an opening in the opaque material to expose the sunken hole of the protruding portion and another part of the protruding portion around the sunken hole.

6. The method of claim 5, wherein an area of the opening is about 11.1 to 1.5 times of an area of the sunken hole.

7. The method of claim 6, wherein the area of the opening is 1.1 times of the area of the sunken hole.

8. The method of claim 4, wherein the light-impervious encapsulant is fabricated by the steps of:
disposing the chip carrier with the sensor chip encapsulated by the transparent encapsulant in an encapsulation mold, and having the protruding portion of the transparent encapsulant abut against a top surface of a mold cavity of the encapsulation mold;
filling the mold cavity with a molding resin; and
removing the encapsulation mold so as to form the light-impervious encapsulant encapsulating the transparent encapsulant, with the protruding portion of the transparent encapsulant being exposed from the light-impervious encapsulant.

9. The method of claim 8, wherein a distance from a surface of the chip carrier to a top edge of the protruding portion of the transparent encapsulant is greater than a distance from the surface of the chip carrier to the top surface of the mold cavity of the encapsulation mold.

10. The method of claim 1, wherein the transparent encapsulant is only formed on a side of the chip carrier where the sensor chip is disposed, so as to encapsulate the sensor chip.

11. The method of claim 1, wherein the transparent encapsulant is formed on both sides of the chip carrier and encapsulates the sensor chip.

12. The method of claim 1, wherein the light-pervious portion is a concave portion formed at a surface of the transparent encapsulant.

13. The method of claim 12, wherein the light-impervious encapsulant is fabricated by the steps of:
providing an encapsulation mold having a protruding portion formed on a top surface of a mold cavity thereof, wherein the protruding portion of the encapsulation mold corresponds in position to the concave portion of the transparent encapsulant;
filling the encapsulation mold with a molding resin; and
removing the encapsulation mold so as to form the light-impervious encapsulant encapsulating the transparent encapsulant, with an opening being formed in the light-impervious encapsulant to expose the concave portion of the transparent encapsulant.

14. The method of claim 13, wherein an area of the protruding portion of the encapsulation mold is about 1.1 to 1.5 times of an area of the concave portion of the transparent encapsulant.

15. The method of claim 14, wherein the area of the protruding portion of the encapsulation mold is 1.1 times of the area of the concave portion of the transparent encapsulant.

16. The method of claim 13, wherein a distance from a surface of the chip carrier to the surface of the transparent encapsulant is 0.05 mm to 0.15 mm greater than a distance from the surface of the chip carrier to a surface of the protruding portion of the encapsulation mold.

17. The method of claim 12, wherein the light-impervious encapsulant is fabricated by the steps of:
providing an encapsulation mold, and allowing the surface of the transparent encapsulant formed with the concave portion to abut against a top surface of a mold cavity of the encapsulation mold;
filling the encapsulation mold with a molding resin; and
removing the encapsulation mold so as to form the light-impervious encapsulant encapsulating the transparent encapsulant, with the surface of the transparent encapsulant formed with the concave portion being flush with a surface of the light-impervious encapsulant and being exposed from the light-impervious encapsulant.

18. The method of claim 17 further comprising covering the surface of the transparent encapsulant exposed from the light-impervious encapsulant with an opaque material, wherein an opening is formed in the opaque material at a position corresponding to the concave portion of the transparent encapsulant to expose the concave portion.

19. The method of claim 18, wherein an area of the opening is about 1.1 to 1.5 times of an area of the concave portion.

20. The method of claim 19, wherein the area of the opening is 1.1 times of the area of the concave portion.

21. The method of claim 1, wherein a rough structure is formed on a contact surface between the transparent encapsulant and the light-impervious encapsulant.

22. A sensor semiconductor device comprising:
a chip carrier;
at least one sensor chip disposed on and electrically connected to the chip carrier, wherein the sensor chip has a sensor zone;
a transparent encapsulant encapsulating the sensor chip and a part of the chip carrier, wherein the transparent encapsulant has a light-pervious portion formed at a position corresponding to and above the sensor zone of the sensor chip; and
a light-impervious encapsulant encapsulating the transparent encapsulant, with the light-pervious portion of the transparent encapsulant being exposed from the light-impervious encapsulant.

23. The sensor semiconductor device of claim 22, wherein the chip carrier is a lead frame having a die pad and a plurality of leads disposed around the chip carrier, the at least one sensor chip is disposed on the die pad and is electrically connected to inner ends of the leads via a plurality of bonding wires, and outer ends of the leads are exposed from the transparent encapsulant and the light-impervious encapsulant.

24. The sensor semiconductor device of claim 23, wherein the lead frame is made of copper (Cu), surfaces of the die pad and the inner ends of the leads are plated with silver (Ag), and surfaces of the outer ends of the leads are plated with tin (Sn) or a solder material.

25. The sensor semiconductor device of claim 22, wherein the light-pervious portion is a protruding portion formed on a surface of the transparent encapsulant, and a sunken hole is formed in the protruding portion for penetration of light.

26. The sensor semiconductor device of claim 25 further comprising an opaque material covering a part of the protruding portion, and an opening formed in the opaque material to expose the sunken hole of the protruding portion and another part of the protruding portion around the sunken hole.

27. The sensor semiconductor device of claim 26, wherein an area of the opening is about 1.1 to 1.5 times of an area of the sunken hole.

28. The sensor semiconductor device of claim 27, wherein the area of the opening is 1.1 times of the area of the sunken hole.

29. The sensor semiconductor device of claim 22, wherein the transparent encapsulant is only formed on a side of the chip carrier where the sensor chip is disposed, so as to encapsulate the sensor chip.

30. The sensor semiconductor device of claim 22, wherein the transparent encapsulant is formed on both sides of the chip carrier and encapsulates the sensor chip.

31. The sensor semiconductor device of claim 22, wherein the light-pervious portion is a concave portion formed at a surface of the transparent encapsulant.

32. The sensor semiconductor device of claim 31, wherein a surface of the light-impervious encapsulant is formed with an opening therein for exposing the concave portion of the transparent encapsulant.

33. The sensor semiconductor device of claim 32, wherein an area of the opening is about 1.1 to 1.5 times of an area of the concave portion of the transparent encapsulant.

34. The sensor semiconductor device of claim 33, wherein the area of the opening is 1.1 times of the area of the concave portion of the transparent encapsulant.

35. The sensor semiconductor device of claim 31, wherein the surface of the transparent encapsulant formed with the concave portion is flush with a surface of the light-impervious encapsulant and is exposed from the light-impervious encapsulant.

36. The sensor semiconductor device of claim 35 further comprising an opaque material covering the surface of the transparent encapsulant exposed from the light-impervious encapsulant, and an opening formed in the opaque material at a position corresponding to the concave portion of the transparent encapsulant to expose the concave portion.

37. The sensor semiconductor device of claim 36, wherein an area of the opening is about 1.1 to 1.5 times of an area of the concave portion.

38. The sensor semiconductor device of claim 37, wherein the area of the opening is 1.1 times of area of the concave portion.

39. The sensor semiconductor device of claim 22, wherein a rough structure is formed on a contact surface between the transparent encapsulant and the light-impervious encapsulant.
